(19) United States
(12) Patent Application Publication
(10) Pub. No.: US 2016/0177435 A1
(43) Pub. Date: Jun. 23, 2016

(54) EVAPORATION DEVICE

(71) Applicant: Shenzhen China Star Optoelectronics Technology Co., Shenzhen, Guangdong (CN)

(72) Inventors: Jinchuan LI, Shenzhen, Guangdong (CN); Tsung-Yuan Wu, Shenzhen, Guangdong (CN)

(73) Assignee: Shenzhen China Star Optoelectronics Technology Co. Ltd., Shenzhen, Guangdong (CN)

(21) Appl. No.: 14/433,632

(22) PCT Filed: Dec. 30, 2014
(86) PCT No.: PCT/CN2014/095554

§ 371 Date: Apr. 3, 2015

(30) Foreign Application Priority Data
Dec. 19, 2014 (CN) 2014108024860

(51) Int. Cl. C23C 14/24

(52) U.S. Cl. CPC C23C 14/24

(57) ABSTRACT

The present invention provides an evaporation device which contains a vacuum chamber providing a vacuum environment; an evaporation source housed in the vacuum chamber, the evaporation source providing Li3N for evaporation and heating up Li3N to produce Li; a positioning system located oppositely to the evaporation source, the positioning system positioning a substrate for depositing Li thereon; a condensation pump connected with the vacuum chamber for vacuuming the vacuum chamber; and a molecular pump connected with the vacuum chamber for maintaining a degree of vacuum in the vacuum chamber. The evaporation device is capable of achieving a high degree of vacuum in the vacuum chamber, and as such enhancing product life.

### BACKGROUND OF THE INVENTION

1. Field of the Invention

The present invention generally relates to semiconductor manufacturing, and particularly relates to evaporation devices.

2. The Related Arts

Organic Light-Emitting Diode (OLED), due to its active light generation, fast response, flexibility, significantly reduced thickness, is considered one of the most promising technologies. Major manufacturers around the globe have continuously invested significant resources in OLED research and development so as to meet growing demands.

Among OLED related technologies, White OLED (WOLED) is gaining popularity in large TV panels and growing number of manufacturers are attracted in the related research and development. Currently WOLED elements are produced using layered R/G/B structure and color filters are employed to achieve various colors. The layered structure usually requires a Charge Generate Layer (CGL) to produce electrons for blue-light layer and holes for red/green-light layer. Li is a common element for the formation of CGL. Li is an active element and usually Li3N is used instead for greater safety. In addition Li3N is suitable for evaporation as only a temperature of 500° is required. However Li3N would, after heating up, release large amount of N2 and H2. Conventional evaporation devices employ a condensation pump to maintain a desired degree of vacuum but to remove H2, due to its low molecular weight, takes an extended period of time. The degree of vacuum is therefore compromised, and the produced WOLED would suffer inferior product life.

### SUMMARY OF THE INVENTION

The technical issue to be addressed by the present invention is to provide an evaporation device capable of achieving a high degree of vacuum during an evaporation process.

To address the technical issue, the present invention provides an evaporation device which contains a vacuum chamber providing a vacuum environment; an evaporation source housed in the vacuum chamber, the evaporation source providing Li3N for evaporation and heating up Li3N to produce Li; a positioning system located oppositely to the evaporation source, the positioning system positioning a substrate for depositing Li thereon; a condensation pump connected with the vacuum chamber for vacuuming the vacuum chamber; and a molecular pump connected with the vacuum chamber for maintaining a degree of vacuum in the vacuum chamber.

Preferably, the molecular pump and the condensation pump are oppositely positioned.

Preferably, the molecular pump extracts gases of lower molecular weights so that the degree of vacuum in the vacuum chamber is maintained below E-5 Pa.

Preferably, the molecular pump is operated above 27,500 rpm.

Preferably, the molecular pump is a high-speed molecular pump, and the high-speed molecular pump is operated above 35,000 rpm.

Preferably, the high-speed molecular pump is operated above 42,300 rpm.

Preferably, the high-speed molecular pump is operated above 51,000 rpm.

Preferably, the evaporation device is for depositing Li on Organic Light-Emitting Diode (OLED).

Preferably, the molecular pump extracts H2 produced when Li3N is heated up.

The advantage of the present invention is that, by achieving a high-degree of vacuum in the vacuum chamber, products produced from the evaporation devices do not suffer reduced product life due to compromised vacuum environment.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic diagram showing an evaporation device according to an embodiment of the present invention.

### DETAILED DESCRIPTION OF THE PREFERRED EMBODIMENTS

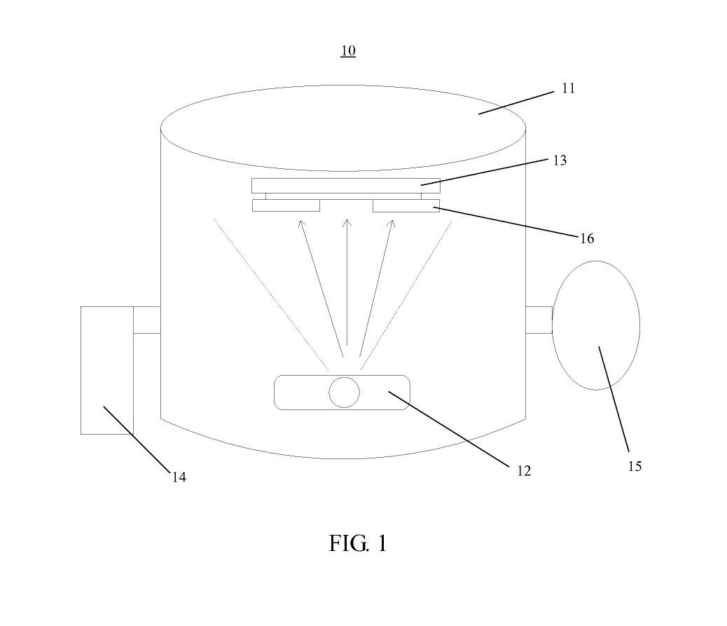

As illustrated in FIG. 1, the present invention provides an evaporation device 10 according to an embodiment of the present invention. As illustrated, the evaporation device 10 contains a vacuum chamber 11, an evaporation source 12, a positioning system 13, a condensation pump 14, and a molecular pump 15. The vacuum chamber 11 provides a vacuum environment. The evaporation source 12 is housed in the vacuum chamber 11, and provides Li3N for evaporation and heats up Li3N so that Li is produced. The positioning system 13 is located oppositely to the evaporation source 12, and positions at least a substrate 16 so that Li is deposited on the substrate 16. The condensation pump 14 is connected with the vacuum chamber 11 for vacuuming the vacuum chamber 11. The molecular pump 15 is connected with the vacuum chamber 11 to maintain a degree of vacuum in the vacuum chamber 11.

In the present embodiment, the molecular pump 15 and the condensation pump 14 are positioned oppositely and independently. Normally, only the condensation pump 14 is turned on so that the degree of vacuum in the vacuum chamber 11 is maintained below E-5 Pa. When the evaporation device 10 is used for WOLED, Li3N from the evaporation source 12 is heated up and the degree of vacuum in the vacuum chamber 11 is reduced to, for example, E-4. The molecular pump 15 then is turned on to extract those gases of lower molecular weights such as the H2 produced when Li3N is heated up, so that the degree of vacuum in the vacuum chamber 11 is maintained above E-5 Pa. In other words, the vacuum chamber 11 is constantly maintained at a high degree of vacuum so as to prevent reduced product life due to compromised vacuum environment.

In the present embodiment, the molecular pump 15 is operated above 27,500 rpm or, if a high-speed molecular pump 15 is adopted, the speed can be more than 35,000 rpm. Preferably, the high-speed molecular pump is operated at 42,300 rpm or 51,000 rpm. The evaporation device 10 of the present embodiment is mainly utilized for depositing Li on OLED.

As described above, the evaporation device 10 contains a vacuum chamber 11 providing a vacuum environment; an evaporation source 12 housed in the vacuum chamber 11, the evaporation source 12 providing Li3N for evaporation and heating up Li3N to produce Li; a positioning system 13 located oppositely to the evaporation source 12, the positioning system 13 positioning at least a substrate 16 for depositing Li thereon; a condensation pump 14 connected with the vacuum chamber 11 for vacuuming the vacuum chamber 11; and a molecular pump 15 connected with the vacuum chamber 11 for maintaining a degree of vacuum in the vacuum chamber 11.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. An evaporation device comprising:
a vacuum chamber providing a vacuum environment;
an evaporation source housed in the vacuum chamber, the evaporation source providing Li3N for evaporation and heating up Li3N to produce Li;
a positioning system located oppositely to the evaporation source, the positioning system positioning a substrate for depositing Li thereon;
a condensation pump connected with the vacuum chamber for vacuuming the vacuum chamber; and
a molecular pump connected with the vacuum chamber for maintaining a degree of vacuum in the vacuum chamber.

2. The evaporation device as claimed in claim 1, wherein the molecular pump and the condensation pump are oppositely positioned.

3. The evaporation device as claimed in claim 1, wherein the molecular pump extracts gases of lower molecular weights so that the degree of vacuum in the vacuum chamber is maintained below E-5 Pa.

4. The evaporation device as claimed in claim 1, wherein the molecular pump is operated above 27,500 rpm.

5. The evaporation device as claimed in claim 1, wherein the molecular pump is a high-speed molecular pump; and the high-speed molecular pump is operated above 35,000 rpm.

6. The evaporation device as claimed in claim 5, wherein the high-speed molecular pump is operated at 42,300 rpm.

7. The evaporation device as claimed in claim 5, wherein the high-speed molecular pump is operated at 51,000 rpm.

8. The evaporation device as claimed in claim 1, wherein the evaporation device is for depositing Li on Organic Light-Emitting Diode (OLED).

9. The evaporation device as claimed in claim 1, wherein the molecular pump extracts H2 produced when Li3N is heated up.

10. An evaporation device comprising:
a vacuum chamber providing a vacuum environment;
an evaporation source housed in the vacuum chamber, the evaporation source providing Li3N for evaporation and heating up Li3N to produce Li;
a positioning system located oppositely to the evaporation source, the positioning system positioning a substrate for depositing Li thereon;
a condensation pump connected with the vacuum chamber for vacuuming the vacuum chamber; and
a molecular pump connected with the vacuum chamber for maintaining a degree of vacuum in the vacuum chamber;
wherein the molecular pump extracts gases of lower molecular weights so that the degree of vacuum in the vacuum chamber is maintained below E-5 Pa.

11. The evaporation device as claimed in claim 10, wherein the molecular pump is operated above 27,500 rpm.

12. The evaporation device as claimed in claim 10, wherein the molecular pump is a high-speed molecular pump; and the high-speed molecular pump is operated above 35,000 rpm.

13. The evaporation device as claimed in claim 12, wherein the high-speed molecular pump is operated at 42,300 rpm.

14. The evaporation device as claimed in claim 12, wherein the high-speed molecular pump is operated at 51,000 rpm.

15. The evaporation device as claimed in claim 10, wherein the evaporation device is for depositing Li on Organic Light-Emitting Diode (OLED).

16. The evaporation device as claimed in claim 10, wherein the molecular pump extracts H2 produced when Li3N is heated up.
